(19) United States
(12) Patent Application Publication
(10) Pub. No.: US 2012/0018820 A1
(43) Pub. Date: Jan. 26, 2012

(54) SEMICONDUCTOR DEVICE

(75) Inventors: Masaki UTSUMI, Kyoto (JP); Kyoko FUJII, Osaka (JP); Takahiro NAKANO, Kyoto (JP)

(73) Assignee: PANASONIC CORPORATION, Osaka (JP)

(21) Appl. No.: 13/247,226

(22) Filed: Sep. 28, 2011

Related U.S. Application Data
(63) Continuation of application No. PCT/JP2010/001024, filed on Feb. 18, 2010.

(30) Foreign Application Priority Data
Apr. 1, 2009 (JP) 2009-089574

(51) Int. Cl. H01L 29/84

(52) U.S. Cl. 257/416; 257/E29.324

(57) ABSTRACT

A semiconductor device includes a converter that converts an acoustic pressure into an electrical signal and an amplifier element that includes an amplifier circuit that amplifies the electrical signal outputted from the converter. The converter includes a pedestal including a cavity formed from an upper face to a lower face thereof, and a vibration film located so as to cover an opening of the cavity on the side of the upper face. The vibration film vibrates in accordance with the acoustic pressure to thereby convert the acoustic pressure into an electrical signal. The amplifier element is located under the converter so as to cover the cavity.

### CROSS REFERENCE TO RELATED APPLICATION

This is a continuation application of PCT application No. PCT/JP2010/001024 filed on Feb. 18, 2010, designating the United States of America.

### BACKGROUND OF THE INVENTION

(1) Field of the Invention

The present invention relates to a semiconductor device that converts a sound into an electrical signal.

(2) Description of the Related Art

There has constantly been a demand for further reduction in size and weight of portable apparatuses such as mobile phones, and microphones mounted in these apparatuses have also been a target of reduction in size and weight, to meet such a demand.

For example, as disclosed in Japanese Unexamined Patent Application Publication No. 2003-348696 (Patent Reference 1), a converter that converts a sound into an electrical signal is mounted on a substrate having a sound hole, and the microphone is formed into a substrate module by connecting a substrate electrode and an electrode for the converter by a bonding wire, and connecting also the substrate electrode and an electrode for an amplifier element that amplifies the electrical signal outputted from the converter by a bonding wire, for the purpose of reduction in size and weight.

FIG. 11 is a cross-sectional view showing a configuration of the semiconductor device according to Patent Reference 1. As shown in FIG. 11, the conventional semiconductor device 1100 includes a converter 1102 having a vibration film 1101 and amplifier elements 1103 and 1104 that process a signal from the converter 1102, mounted on a circuit substrate 1105. These are covered with a metal housing 1107 having sound holes 1106. In the semiconductor device 1100 thus configured, a sonic wave transmitted through the sound holes 1106 causes the vibration film 1101 to vibrate, and a sound is detected upon detecting an electrical signal generated from the vibration of the vibration film 1101.

However, the semiconductor device 1100 according to Patent Reference 1 has a drawback in that sufficient reduction in size cannot be achieved. The converter 1102 and the amplifier elements 1103 and 1104 are mounted side by side on the circuit substrate 1105 which inevitably makes the circuit substrate 1105 larger in size, resulting in failure to reduce the size of the semiconductor device 1100 as desired.

Therefore a different semiconductor device has been proposed, for example in Japanese Unexamined Patent Application Publication No. 2007-263677 (Patent Reference 2), in which a converter and an amplifier element are stacked so as to reduce the size of the semiconductor device.

FIG. 12 is a cross-sectional view showing a configuration of the semiconductor device according to Patent Reference 2. As shown in FIG. 12, in the semiconductor device 1200 according to Patent Reference 2 a converter 1202 having a vibration film 1201 and a semiconductor substrate 1203 that processes a signal from the converter 1202 are stacked and mounted on a circuit substrate 1204. The converter 1202, the semiconductor substrate 1203, and the circuit substrate 1204 are covered with a shield cap 1206 having a sound hole 1205, and the semiconductor substrate 1203 includes a recess 1207 formed on its surface at a position corresponding to the vibration film 1201.

With such a configuration, a sound is detected on the basis of the vibration of the vibration film 1201 caused by an acoustic pressure transmitted through the sound hole 1205.

### SUMMARY OF THE INVENTION

In the semiconductor device 1200 according to Patent Reference 2, in order to enable the vibration film 1201 of the converter 1202 to vibrate, the recess 1207 has to be formed on the semiconductor substrate 1203 that includes an amplifier circuit, however it may be impossible in the case where the semiconductor substrate 1203 is not sufficiently thick.

In addition, microphone sensitivity which is generally considered as the key factor in performance of a microphone is proportional to a size of a sealed space at the rear of the vibration film 1201 (hereinafter referred to as rear space), such that the larger the rear space is the higher the microphone sensitivity becomes. In other words, in order to achieve higher microphone sensitivity, the rear space has to be large. It is to be noted that the microphone sensitivity of the semiconductor device herein referred to is synonymous with pressure detection sensitivity of the vibration film with respect to an acoustic pressure.

Accordingly, the configuration of the semiconductor device 1200 has a drawback in that a sufficient size of the recess 1207 cannot be secured because of the requirement for a smaller size, which results in degraded microphone sensitivity.

Conversely, forming the recess 1207 in a larger size for obtaining sufficient microphone sensitivity inevitably makes the semiconductor substrate 1203 thicker, thus making it difficult to reduce the height of the semiconductor device 1200.

Accordingly, an object of the present invention is to provide a semiconductor device that is small in size yet has high microphone sensitivity.

In an aspect, the present invention provides a semiconductor device including a converter that converts an acoustic pressure into an electrical signal and a semiconductor element that includes an amplifier circuit that amplifies the electrical signal converted by the converter. The converter includes a pedestal including a through hole formed from an upper face to a lower face thereof, and a vibration film located so as to cover an opening of the through hole on the side of the upper face and configured to vibrate in accordance with the acoustic pressure to thereby convert the acoustic pressure into an electrical signal, and the semiconductor element is located under the converter so as to cover the through hole.

In the above semiconductor device the converter and the semiconductor element are vertically stacked, and therefore the semiconductor device can be manufactured in a smaller size and lighter weight. In addition, since the converter includes the vibration film on the upper face of the pedestal, which is the opposite side of the semiconductor element, a rear space can be secured behind the vibration film with respect to the direction in which the sound proceeds, without the need to form a recess in the semiconductor element. Consequently, the microphone sensitivity of the semiconductor device can be improved.

Preferably, the semiconductor element may include a recess, and the recess may be open toward the through hole.

In this case, the rear space of a larger capacity can be secured, which leads to increased microphone sensitivity and hence to further improvement of sound quality.

The semiconductor device may further include a first bump formed on the lower face of the pedestal. The pedestal may include a first through conductor provided therethrough from the upper face to the lower face, and the vibration film and the semiconductor element may be electrically connected through the first through conductor and the first bump.

Such a configuration, in which the converter and the semiconductor element are electrically connected through a wire, can make the plan-view size of the semiconductor device smaller compared with the stacked structure.

Preferably, the semiconductor device may further include an underfill provided around the first bump.

Such an arrangement increases adhesion strength between the pedestal and the semiconductor element, thereby improving the impact resistance of the semiconductor device.

Preferably, the converter and the semiconductor element may have substantially the same downwardly projected area.

In this case, since the converter and the semiconductor element stacked on each other are formed in the same plan-view size, in particular the semiconductor element constituting the lower part of the stacked structure can be formed in a smaller plan-view size, and therefore the semiconductor device can be manufactured in a still smaller size and a still lighter weight. In addition, in the manufacturing process two wafers including a plurality of semiconductor elements and a plurality of converters, respectively, are bonded together and then diced so that individual bonded pieces each including one semiconductor element and one converter can be obtained at the same time, which contributes to reducing the processing time, and hence the manufacturing cost.

The semiconductor device may further include a second bump formed on a lower face of the semiconductor element, and a substrate provided under the semiconductor element with the second bump therebetween and including an electrical wiring through which an electrical signal amplified by the semiconductor element is transmitted outside. The semiconductor element may include a second through conductor formed therethrough from an upper face to the lower face, and the electrical wiring and the second through conductor may be electrically connected through the second bump, and the substrate and the semiconductor element may have substantially the same downwardly projected area.

In this case, since the converter, the semiconductor element, and the substrate stacked on each other are formed in the same plan-view size, in particular the substrate constituting the lower part of the stacked structure can be formed in a smaller plan-view size, and therefore the semiconductor device can be manufactured in a still smaller size and a still lighter weight. In addition, in the manufacturing process two wafers bonded together, including a plurality of semiconductor elements and a plurality of converters, respectively, are bonded to a parent substrate including a plurality of substrates, and then diced so that individual bonded pieces each including one semiconductor element, one converter, and one substrate can be obtained at the same time, which contributes to reducing the processing time, and hence the manufacturing cost.

The semiconductor device may further include a shield cap formed so as to cover the converter and the semiconductor element, and the shield cap may have its peripheral edge fixed to the substrate, and may include a sound hole through which the acoustic pressure is transmitted to the vibration film.

Such a configuration prevents the semiconductor device from being affected by an impact or a noise from outside such as an electromagnetic wave.

The sound hole may be formed at an upper portion of the through hole.

Such a configuration facilitates the vibration film to efficiently vibrate, thereby improving the microphone sensitivity of the semiconductor device.

Further, the shield cap may include a frame surrounding the lateral faces of the converter and the semiconductor element, and a plate fixed to the frame.

Such a configuration contributes to reducing the cost.

In another aspect, the present invention provides a semiconductor device including a converter that converts an acoustic pressure into an electrical signal, a semiconductor element that includes an amplifier circuit that amplifies the electrical signal converted by the converter, and a substrate that transmits the electrical signal amplified by the semiconductor element to outside. The converter includes a pedestal including a first through hole penetrating therethrough from an upper face to a lower face thereof, and a vibration film located on the lower face of the pedestal so as to cover an opening of the first through hole on the side of the lower face and configured to vibrate in accordance with the acoustic pressure to thereby convert the acoustic pressure into an electrical signal. The semiconductor element is located under the converter and includes a second through hole penetrating therethrough from an upper face to a lower face thereof, the second through hole being located under the first through hole.

The substrate is located under the semiconductor element and includes a third through hole penetrating therethrough from an upper surface to a lower surface thereof, the third through hole being located under the first through hole. The semiconductor device further includes a shield cap having its peripheral edge fixed to the substrate so as to cover the converter and the semiconductor element.

In this semiconductor device, the converter and the semiconductor element are vertically stacked, and therefore the semiconductor device can be manufactured in a smaller size and lighter weight. In addition, since the configuration allows a sound to enter from the side of the substrate, the rear space, i.e., the closed space behind the vibration film with respect to the direction in which the sound proceeds, can be secured with a larger capacity, which leads to increased microphone sensitivity and hence to further improvement of sound quality.

This semiconductor device is the same as the first defined semiconductor device in that the both include the converter that converts an acoustic pressure into an electrical signal and the semiconductor element that includes the amplifier circuit that amplifies the electrical signal converted by the converter, and in that the converter includes the pedestal with the through hole and the vibration film provided so as to cover the opening of the through hole, that the through hole is located behind the vibration film with respect to the direction of the acoustic pressure incident on the vibration film, and that the converter and the semiconductor element are located so as to overlap in the incident direction of the acoustic pressure.

The shield cap may be in contact with the upper face of the pedestal.

In this case, the converter and the semiconductor element can be electrically connected through a wire, and the plan-view size of the semiconductor device can be made smaller compared with the stacked structure.

In addition, the semiconductor device may further include a bump and an underfill provided on the lower face of the pedestal. The converter and the semiconductor element may be electrically connected through the bump and the underfill may be provided around the bump.

Such a configuration allows the converter and the semiconductor element to be vertically stacked, thereby enabling reduction in size and weight of the semiconductor device.

Further, the bump and the underfill may be provided so as to continuously surround the opening of the first through hole opposing the lower face of the pedestal.

In this case, the acoustic pressure incident on the vibration film through the second and the third through hole can be prevented from leaking toward the shield cap through a gap between the bumps. Such a configuration facilitates the vibration film to efficiently vibrate with the acoustic pressure incident on the semiconductor device from outside, thereby improving the microphone sensitivity of the semiconductor device.

Further, the shield cap may include a frame surrounding the lateral faces of the converter and the semiconductor element, and a plate fixed to the frame.

A method of manufacturing the semiconductor device is as follows. The semiconductor device includes a converter that converts an acoustic pressure into an electrical signal, the converter including a pedestal that includes a first through hole formed from an upper face to a lower face thereof, and a vibration film located on the lower face of the pedestal so as to cover the first through hole and configured to vibrate in accordance with the acoustic pressure to thereby convert the acoustic pressure into an electrical signal; a semiconductor element that includes a second through hole and amplifies the electrical signal converted by the converter; a substrate that includes a third through hole and transmits the electrical signal amplified by the semiconductor element to outside; a frame surrounding a lateral face of the converter and the semiconductor element; and a plate fixed to the frame. The method includes assembling a first parent material including a plurality of the substrates, a second parent material including a plurality of the frames, and a third parent material including a plurality of the plates; simultaneously cutting with a dicing blade the first parent material, the second parent material, and the third parent material that have been assembled, to thereby obtain a plurality of the semiconductor devices.

Cutting thus the first parent material, the second parent material, and the third parent material simultaneously with the dicing blade enables reduction of the manufacturing cost of the semiconductor device.

The foregoing method may further include attaching a tape on a surface of the first parent material opposing the second parent material between the assembling and the cutting; and removing the tape from the first parent material that has been cut, after the cutting.

Since the tape is provided so as to cover the lower end of the third through hole in the process of cutting with the dicing blade, the vibration film can be easily protected from being damaged by current force of cutting water or cut chips. Consequently, the yield of the manufacturing process can be improved.

Through the foregoing arrangement, the present invention provides a semiconductor device that is small in size yet has high microphone sensitivity, and a manufacturing method of such a semiconductor device.

### FURTHER INFORMATION ABOUT TECHNICAL BACKGROUND TO THIS APPLICATION

The disclosure of Japanese Patent Application No. 2009-089574 filed on Apr. 1, 2009 including specification, drawings and claims is incorporated herein by reference in its entirety.

The disclosure of PCT application No. PCT/JP2010/001024 filed on Feb. 18, 2010, including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a cross-sectional view showing a configuration of a semiconductor device according to an embodiment 1;

FIG. 2 is a cross-sectional view showing a configuration of a semiconductor device including an amplifier element having a recess;

FIG. 3 is a cross-sectional view showing a configuration of a semiconductor device according to an embodiment 2;

FIG. 4 is a cross-sectional view showing a configuration of a semiconductor device including a shield cap in contact with an upper face of a pedestal;

FIG. 5 is a cross-sectional view showing a configuration of a semiconductor device according to an embodiment 3;

FIG. 6 is a cross-sectional view showing a configuration of a semiconductor device including a converter and an amplifier element having the same plan-view size;

FIG. 7 is a cross-sectional view showing a configuration of a semiconductor device without a shield cap, in which a converter, an amplifier element, and a substrate have the same plan-view size;

FIG. 8 is a cross-sectional view showing a configuration of a semiconductor device according to an embodiment 4;

FIG. 9 is a series of plan views for explaining a manufacturing method of the semiconductor device according to the embodiment 4;

FIG. 10 is a cross-sectional view showing another configuration of a semiconductor device according to the embodiment 4;

FIG. 11 is a cross-sectional view showing a configuration of the conventional semiconductor device according to Patent Reference 1; and

FIG. 12 is a cross-sectional view showing a configuration of the conventional semiconductor device according to Patent Reference 2.

### DESCRIPTION OF THE PREFERRED EMBODIMENTS

Hereafter, embodiments of a semiconductor device and a manufacturing method thereof according to the present invention will be described referring to the drawings. Description of constituents given the same numeral may be skipped. The drawings schematically illustrate the respective constituents for the sake of clarity, and do no always accurately reflect the shapes and sizes. Further, for easier identification of openings in the accompanying drawings, the edges of the openings are not drawn.

### Embodiment 1

The semiconductor device according to an embodiment 1 includes a converter that converts an acoustic pressure into an electrical signal and a semiconductor element that includes an amplifier circuit that amplifies the electrical signal converted by the converter. The converter includes a pedestal including a through hole formed from an upper face to a lower face thereof, and a vibration film located so as to cover an opening of the through hole on the side of the upper face and configured to vibrate in accordance with the acoustic pressure to thereby convert the acoustic pressure into an electrical signal, and the semiconductor element is located under the converter so as to cover the through hole.

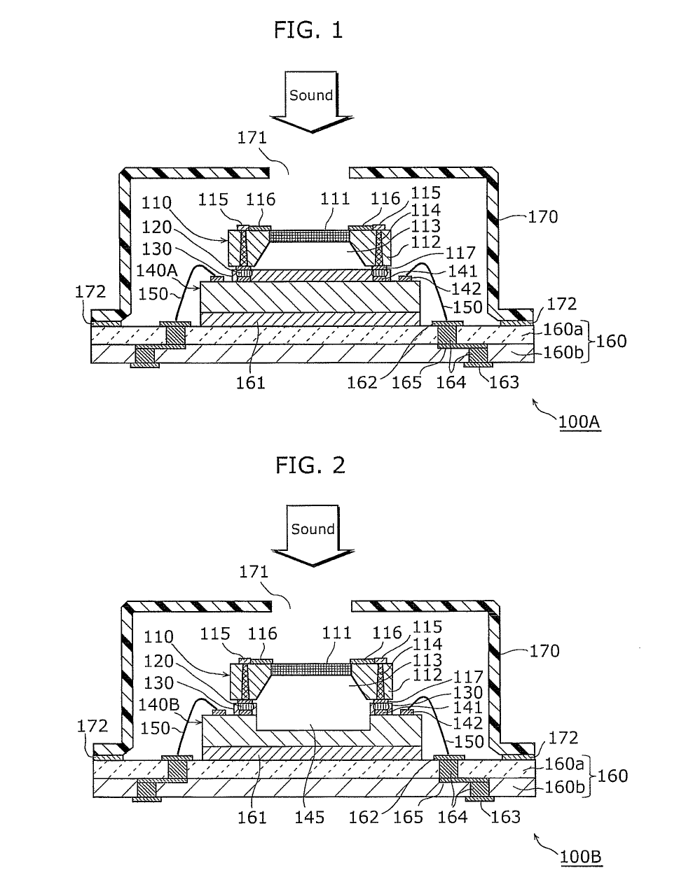

FIG. 1 is a cross-sectional view showing a configuration of a semiconductor device according to an embodiment 1.

As shown in FIG. 1, the semiconductor device 100A according to this embodiment includes a converter 110, bumps 120, a converter underfill 130, an amplifier element 140A, wires 150, a substrate 160, and a shield cap 170.

The converter 110 includes a vibration film 111 and a pedestal 112, and converts an acoustic pressure into an electrical signal.

The vibration film 111 is located on an upper face of the pedestal 112, so as to cover an opening of a cavity 113, which is a through hole formed so as to penetrate the pedestal 112 from the upper face to a lower face, on the side of the upper face. The vibration film 111 vibrates in accordance with an acoustic pressure from outside the semiconductor device 100A, to thereby convert a sound into an electrical signal. More specifically, the vibration film 111 has a bilayer parallel plate structure including a passive film fixed in a predetermined shape, and an active film that vibrates with a sound. A gap is provided between the passive film and the active film, and a change in size of the gap between the passive film and the active film causes a change in electrical capacitance therebetween, in accordance with the theory of capacitance change. Thus, the vibration film 111 converts an acoustic pressure into an electrical signal on the basis of the change in capacitance caused by the vibration of the active film subjected to the acoustic pressure.

The pedestal 112 serves as a base for supporting the vibration film 111, and includes the cavity 113, formed of the through hole penetrating from the upper face to the lower face of the pedestal 112. The vibration film 111 is located so as to cover the opening of the cavity 113 on the side of the upper face. The pedestal 112 also includes a through hole conductor 114, which is a through conductor penetrating through the pedestal 112 from the upper face to the lower face, a converter electrode 115 provided on an upper end portion of the through hole conductor 114, an interconnect 116 formed on the upper face of the pedestal 112 for electrically connecting the converter electrode 115 and the vibration film 111, and a converter electrode 117 provided on a lower end portion of the through hole conductor 114. The converter electrode 117 is electrically connected to the vibration film 111 through the through hole conductor 114, the converter electrode 115, and the interconnect 116. Accordingly, the converter 110 converts a sound inputted from outside the semiconductor device 100A into an electrical signal by means of the vibration film 111, and transmits the electrical signal to the converter electrode 117 on the lower side through the through hole conductor 114.

An oxide layer is provided on the sidewall of the through hole conductor 114. The oxide layer suppresses current leak from the through hole conductor 114 to thereby facilitate the electrical signal from the vibration film 111 to be efficiently transmitted to the converter electrode 117, thus preventing degradation of the sensitivity of the converter 110.

The bumps 120 are located on the lower face of the converter 110, for electrically connection between the converter 110 and the amplifier element 140A. More specifically, the bumps 120 are located right under the converter electrode 117.

The converter underfill 130 is loaded between the converter 110 and the amplifier element 140A so as to enclose the bumps 120 to protect the same. The converter underfill 130 also serves to ensure and maintain the adherence between the converter 110 and the amplifier element 140A. The converter underfill 130 may be constituted of, for example, a thermosetting resin that cures upon being subjected to heat.

The amplifier element 140A is a semiconductor element including an amplifier circuit that amplifies the electrical signal converted by the converter 110, and is located under the converter 110 with the bumps 120 and the converter underfill 130 therebetween. Specifically, the amplifier element 140A includes an internal circuit having the functions of outputting an amplified electrical signal, rectifying the output, processing and outputting a digital signal, and so forth. The amplifier element 140A is provided with electrodes 141 and 142 on an upper face thereof. The electrode 141 is located right under a corresponding one of the bumps 120 and connected to an input terminal of the internal circuit of the amplifier element 140A. Thus, the amplifier circuit in the amplifier element 140A is electrically connected to the vibration film 111 through the electrode 141 and the bump 120. Accordingly, the vibration film 111 of the converter 110 is electrically connected to the input terminal of the internal circuit of the amplifier element 140A through the interconnect 116, the converter electrodes 115 and 117, the through hole conductor 114, and the electrode 141. The electrode 142 is connected to an output terminal of the internal circuit of the amplifier element 140A.

The wire 150 serves to electrically connect the amplifier element 140A and the substrate 160, to thereby transmit the electrical signal amplified by the amplifier element 140A to the substrate 160.

The substrate 160 may be, for example, a resin-based organic substrate. The substrate 160 is fixed to the lower face of the amplifier element 140A with an element adhesive 161, and serves to transmit the electrical signal amplified by the amplifier element 140A to outside the semiconductor device 100A. More specifically, the substrate 160 has a bilayer structure including an upper substrate 160a and a lower substrate 160b, and is provided with a substrate electrode 162 on the upper surface, and a mounting electrode 163 on the lower surface. The substrate electrode 162 and the mounting electrode 163 are electrically connected to each other through contacts 164 provided in the upper substrate 160a and the lower substrate 160b, and a pattern 165 provided on the upper surface of the lower substrate 160b. Here, the substrate electrode 162 is connected to the electrode 142 through the wire 150. Accordingly, the substrate electrode 162, the contact 164, the pattern 165, and the mounting electrode 163 serve as an electrical wiring through which the electrical signal amplified by the amplifier element 140A is transmitted to outside. The substrate 160 may be constituted of a metal material such as Cu or Fe used for a lead frame, or an inorganic material such as a ceramic.

The shield cap 170 includes an orifice 171, and has its peripheral edge fixed to the substrate 160 with a cap adhesive 172 so as to cover the converter 110 and the amplifier element 140A and thus to protect the converter 110 and the amplifier element 140A. The orifice 171 provided in the shield cap 170 serves as a sound hole for transmitting a sound from outside the semiconductor device 100A to the vibration film 111, and is hence located above the vibration film 111. Providing thus the orifice 171 above the vibration film 111 facilitates the acoustic pressure to be transmitted to the vibration film 111 to thereby allow the vibration film 111 to efficiently vibrate, thus contributing to improve the microphone sensitivity of the semiconductor device 100A.

The semiconductor device 100A thus configured converts a sound inputted through the orifice 171 into an electrical signal, on the basis the vibration of the vibration film 111 caused by the sound. Since the vibration film 111 is electrically connected to the input terminal of the internal circuit of the amplifier element 140A through the interconnect 116, the converter electrodes 115, the through hole conductor 114, the converter electrode 117, the bump 120 and the electrode 141, the electrical signal converted by the vibration film 111 is amplified in the amplifier element 140A. Also, the output terminal of the amplifier element 140A is connected to the mounting electrode 163 through the electrode 141, the wire 150, the substrate electrode 162, the contact 164 and the pattern 165. Therefore, the electrical signal amplified in the amplifier element 140A is outputted from the mounting electrode 163.

Thus, the semiconductor device 100A according to this embodiment has a stacked structure in which the substrate 160, the amplifier element 140A and the converter 110 are vertically stacked, and can therefore be manufactured in a smaller size and lighter weight. In addition, since the vibration film 111 of the converter 110 is located on the upper face of the pedestal 112, which is the opposite side of the amplifier element 140A, a rear space can be secured behind the vibration film 111 with respect to the direction in which the sound proceeds, without the need to form a recess in the amplifier element 140A. Consequently, the microphone sensitivity of the semiconductor device 100A can be improved.

The semiconductor device 100A can also be defined as a semiconductor device including the converter 110 that converts a sound into an electrical signal and a semiconductor element that includes an amplifier circuit that amplifies the electrical signal converted by the converter 110, the converter 110 including the pedestal 112 with a through hole and the vibration film 111 provided so as to cover an opening of the through hole, the through hole being located behind the vibration film 111 with respect to the direction of the sound incident on the vibration film 111, and the converter 110 and the semiconductor element being located so as to overlap in the incident direction of the sound.

In addition, the converter 110 and the amplifier element 140A are connected by flip-chip mounting with the bumps 120 therebetween, which allows the semiconductor device to be made smaller compared with the case of connecting by wire bonding.

Further, the converter underfill 130 is loaded around the bumps 120, and therefore the bumps 120 can be protected and the adherence of the converter 110 and the amplifier element 140A can be ensured and maintained. Consequently, the impact resistance of the semiconductor device 100A can be improved.

Further, the shield cap 170 covering the converter 110 and the amplifier element 140A prevents the semiconductor device 100A from being affected by an impact or a noise from outside such as an electromagnetic wave.

Still further, locating the orifice 171 of the shield cap 170 right above the vibration film 111 allows the acoustic pressure based on the sound from outside to be efficiently transmitted to the vibration film 111 so that the vibration film 111 can efficiently vibrate, and therefore the microphone sensitivity of the semiconductor device 100A is improved.

Hereunder, a manufacturing method of the semiconductor device 100A will be described.

First, the substrate 160, provided with the substrate electrode 162 on the upper surface and the mounting electrode 163 on the lower surface, is prepared. Here, the substrate electrode 162 and the mounting electrode 163 on the substrate 160 are electrically connected to each other. Although FIG. 1 depicts the bilayer structure including the upper substrate 160a and the lower substrate 160b, the substrate 160 may be a monolayer substrate in the case where the number of mounting electrodes 163 or rows thereof is not restricted. To increase the number of mounting electrodes 163 or rows thereof, it is preferable to employ a multilayer substrate constituted of two or more layers.

Then the amplifier element 140A is bonded to the upper surface of the substrate 160 with the element adhesive 161, and the electrode 142 of the amplifier element 140A and the substrate electrode 162 are connected by the wire 150.

The electrode 141 and the converter electrode 117 are then connected on the upper face of the amplifier element 140A by means of the bumps 120, so that the converter 110 is fixed. Here, the converter 110 is oriented such that the cavity 113 is located on the side of the amplifier element 140A with respect to the vibration film 111.

Then the converter underfill 130 is introduced in order to ensure and maintain the adherence of the electrode 141, the bumps 120, and the converter electrode 117, and heat is applied for hardening the converter underfill 130. The converter underfill 130 may be provided by application in the process of bonding the electrode 141 and the converter electrode 117 by means of the bumps 120. Alternatively, the converter underfill 130 may be substituted with a tape material or the like.

Finally, the shield cap 170 having the orifice 171 is fixed onto the upper surface of the substrate 160 with the cap adhesive 172 so as to cover the amplifier element 140A and the converter 110 now connected. The semiconductor device 100A according to this embodiment can thus be obtained.

Although the semiconductor device 100A and the manufacturing method thereof according to this embodiment have been described thus far, this embodiment may be modified in various manners.

For example, although the converter underfill 130 is provided for protecting the bumps 120 in the semiconductor device 100A according to this embodiment, the converter underfill 130 may be excluded in the case where sufficient bonding strength between the converter 110 and the amplifier element 140A can be secured without the converter underfill 130. In this case, a space corresponding to the pitch between the bumps 120 is created between the adjacent bumps 120. This allows air in the cavity 113 of the converter 110 to flow out into the space enclosed by the shield cap 170, through the gap between the pedestal 112 and the amplifier element 140A. Accordingly, the volume of the rear space can be increased and hence the pressure detection sensitivity of the vibration film 111 can be improved, which results in improved microphone sensitivity of the semiconductor device 100A.

Although the electrode 142 of the amplifier element 140A and the substrate electrode 162 are connected by the wire 150 before mounting the converter 110 on the upper face of the amplifier element 140A in this embodiment, the converter 110 may be first mounted on the amplifier element 140A before connecting the electrode 142 and the substrate electrode 162 by the wire 150.

Further, the amplifier element may include a recess, and the recess may be open toward the cavity 113.

FIG. 2 is a cross-sectional view showing a configuration of a semiconductor device that includes an amplifier element with a recess.

An amplifier element 140B shown in FIG. 2 is different from the amplifier element 140A in including a recess 145 on the upper face thereof. The recess 145 can be formed through a dry etching or wet etching process.

Providing thus the recess 145 on the upper face of the amplifier element 140B leads to an increase in the volume of the rear space, thereby facilitating the vibration film 111 to efficiently vibrate and improving the pressure detection sensitivity of the vibration film 111. In addition, since the overall size of the amplifier element 140B remain unchanged compared with the amplifier element 140A despite forming the recess 145. Therefore, the semiconductor device 100B shown in FIG. 2 can attain higher microphone sensitivity than the semiconductor device 100A, without incurring an increase in size.

### Embodiment 2

A semiconductor device according to an embodiment 2 includes a converter that converts an acoustic pressure into an electrical signal, a semiconductor element that includes an amplifier circuit that amplifies the electrical signal converted by the converter, and a substrate that transmits the electrical signal amplified by the semiconductor element to outside. The converter includes a pedestal including a first through hole penetrating therethrough from an upper face to a lower face thereof, and a vibration film located on the lower face of the pedestal so as to cover an opening of the first through hole on the side of the lower face and configured to vibrate in accordance with the acoustic pressure to thereby convert the acoustic pressure into an electrical signal. The semiconductor element is located under the converter and includes a second through hole penetrating therethrough from an upper face to a lower face thereof, the second through hole being located under the first through hole. The substrate is located under the semiconductor element and includes a third through hole penetrating therethrough from an upper surface to a lower surface thereof, the third through hole being located under the first through hole. The semiconductor device further includes a shield cap having its peripheral edge fixed to the substrate so as to cover the converter and the semiconductor element.

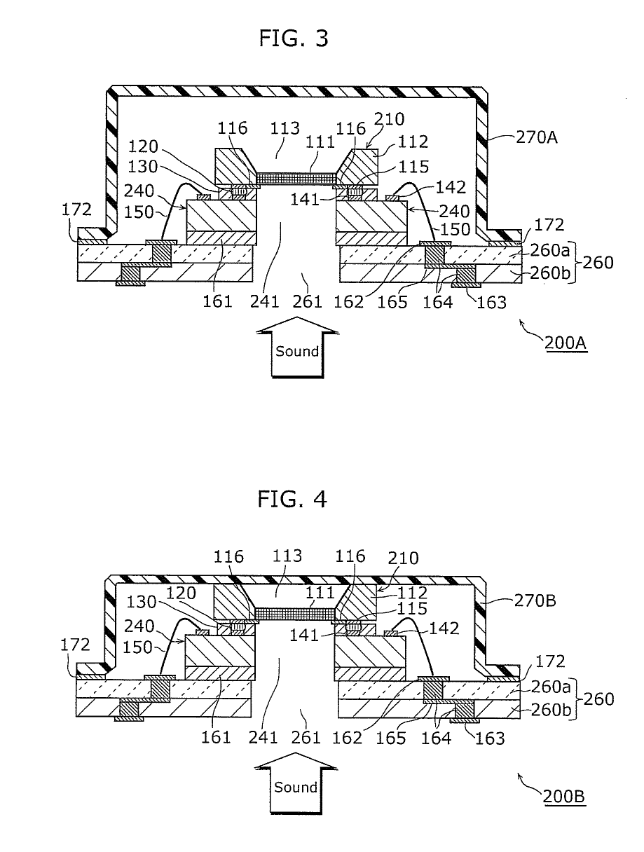

FIG. 3 is a cross-sectional view showing a configuration of a semiconductor device according to the embodiment 2.

The semiconductor device 200A shown in FIG. 3 is generally similar to the semiconductor device 100A shown in FIG. 1, except for a major difference in that a sound is inputted from the side of a substrate 260. Hereunder, description will be given focusing on the difference from the embodiment 1.

A converter 210 is oriented upside down compared with the converter 110, and does not include the through hole conductor 114 and the converter electrode 117. In other words, the converter 210 includes the pedestal 112 and the vibration film 111 located so as to cover an opening of the cavity 113 formed in the pedestal 112 on the side of the lower face.

The bumps 120 are located right under the converter electrode 115.

An amplifier element 240 includes, unlike the amplifier element 140A, an amplifier element through hole 241 corresponding to the second through hole, penetrating from the upper face to the lower face thereof. The amplifier element through hole 241 is located under the cavity 113.

The converter 210 and the amplifier element 240 are bonded by means of the bumps 120 and the converter underfill 130, as in the semiconductor device 100A. Here, the converter underfill 130 is loaded such that the vibration film 111 of the converter 210 and the amplifier element through hole 241 can remain spatially continuous, in other words so as not to interfere with a space defined by the amplifier element through hole 241 as far as the vibration film 111.

The converter underfill 130 and the bumps 120 are disposed so as to continuously surround the opening of the cavity 113 of the pedestal 112 on the side of the lower face.

A substrate 260 includes, unlike the substrate 160, a substrate through hole 261 corresponding to the third through hole, penetrating from the upper surface to the lower surface thereof. The substrate through hole 261 is located under the cavity 113 and the amplifier element through hole 241. Thus, the space defined by the amplifier element through hole 241 and the space defined by the substrate through hole 261 are spatially continuous.

Accordingly, the space surrounded by the substrate through hole 261 and the amplifier element through hole 241 transmits a sound from outside the semiconductor device 200A to the vibration film 111. Then the vibration film 111 vibrates, upon being subjected to the transmitted sound, in accordance with the acoustic pressure of the sound thereby converting the sound into an electrical signal.

The shield cap 270A does not include the orifice 171 unlike the shield cap 170. Here, the space defined by the shield cap 270A, the converter 210, the amplifier element 240 and the substrate 260 constitutes the rear space of the vibration film 111, in this embodiment. More accurately, the space defined by the shield cap 270A, the vibration film 111, the pedestal 112, the amplifier element 240 and the substrate 260 constitutes the rear space. Therefore, the rear space of the semiconductor device 200A can be made larger in volume compared with the rear space of the semiconductor device 100A.

As described above, the semiconductor device 200A according to this embodiment can include a larger rear space of the vibration film 111 than the semiconductor device 100A according to the embodiment 1, without incurring an increase in size of the semiconductor device 200A. Such a configuration contributes to further improving the pressure detection sensitivity of the vibration film 111, thereby further improving the microphone sensitivity of the semiconductor device 200A.

In addition, since the converter underfill 130 and the bumps 120 are disposed so as to continuously surround the opening of the cavity 113 on the side of the lower face of the pedestal 112, the acoustic pressure transmitted from the side of the substrate 260 can be efficiently applied to the vibration film 111 without leaking to the rear space side. Accordingly, the microphone sensitivity of the semiconductor device 200A can be further improved.

The semiconductor device 200A according to this embodiment has the same structure as the semiconductor device 100A and 100B according to the embodiment 1, in that the semiconductor device 200A can also be defined as a semiconductor device including the converter 210 that converts a sound into an electrical signal and a semiconductor element that includes an amplifier circuit that amplifies the electrical signal converted by the converter 210, the converter 210 including the pedestal 112 with a through hole and the vibration film 111 provided so as to cover an opening of the through hole, the through hole being located behind the vibration film 111 with respect to the direction of the sound incident on the vibration film 111, and the converter 210 and the semiconductor element being located so as to overlap in the incident direction of the sound.

The semiconductor device 200A thus configured can be manufactured through generally the same process as that of the semiconductor device 100A, except that positioning is performed because the substrate through hole 261 and the amplifier element through hole 241 are formed in advance in the 260 and the amplifier element 240, respectively.

First, the substrate 260, provided with the substrate electrode 162 on the upper surface and the mounting electrode 163 on the lower surface, is prepared. Here, the substrate electrode 162 and the mounting electrode 163 on the substrate 260 are electrically connected to each other. Although FIG. 3 depicts a bilayer structure including an upper substrate 260a and a lower substrate 260b, the substrate 260 may be a monolayer substrate in the case where the number of mounting electrodes 163 or rows thereof is not restricted. To increase the number of mounting electrodes 163 or rows thereof, it is preferable to employ a multilayer substrate constituted of two or more layers. In addition, although the substrate 260 is assumed to be a popular resin-based organic substrate in the configuration shown in FIG. 3, the substrate 260 may be constituted of a metal material such as Cu or Fe used for a lead frame, or an inorganic material such as a ceramic.

Then the amplifier element 240 is bonded to the upper surface of the substrate 260 with the element adhesive 161 so as to align the amplifier element through hole 241 with the substrate through hole 261 of the substrate 260, and the electrode 142 of the amplifier element 240 and the substrate electrode 162 are connected by the wire 150. Here, the element adhesive 161 is applied so as not to interfere with the substrate through hole 261 of the substrate 260.

The electrode 141 and the converter electrode 115 are then bonded on the upper face of the amplifier element 240 by means of the bumps 120, such that the side of the converter 210 with the vibration film 111 is oriented toward the amplifier element 240.

Then the converter underfill 130 is introduced in order to ensure and maintain the adherence of the electrode 141, the bumps 120, and the converter electrode 115, and heat is applied for hardening the converter underfill 130. The converter underfill 130 may be provided by application in the process of bonding the electrode 141 and the converter electrode 115 by means of the bumps 120. Although the electrode 142 of the amplifier element 240 and the substrate electrode 162 are connected by the wire 150 before mounting the converter 210 on the upper face of the amplifier element 240 in this embodiment, the converter 210 may be first mounted on the amplifier element 240 before connecting the electrode 142 and the substrate electrode 162 by the wire 150.

Here, the converter underfill 130 is loaded such that the vibration film 111 of the converter 210 and the amplifier element through hole 241 can remain spatially continuous, in other words so as not to interfere with the space defined by the amplifier element through hole 241 as far as the vibration film 111. Thus, the substrate through hole 261 of the substrate 260 and the amplifier element through hole 241 are spatially continuous as far as the vibration film 111.

Thereafter, the shield cap 270A is fixed onto the upper surface of the substrate 260 with the cap adhesive 172 so as to cover the amplifier element 240 and the converter 210 now connected. The semiconductor device 200A can thus be obtained.

Although the semiconductor device 200A and the manufacturing method thereof according to this embodiment have been described thus far, this embodiment may be modified in various manners.

For example, the shield cap may be in contact with the upper face of the pedestal 112, i.e., the face of the pedestal 112 opposite the vibration film 111. FIG. 4 is a cross-sectional view showing a configuration of a semiconductor device including the shield cap in contact with the upper face of the pedestal 112. As shown therein, the shield cap 270B is lower in height than the shield cap 270A shown in FIG. 3, because of being in contact with the upper face of the pedestal 112.

Disposing thus the shield cap 270B in contact with the upper face of the pedestal 112 allows the semiconductor device 200B shown in FIG. 4 to be made lower in height than the semiconductor device 200A shown in FIG. 3.

### Embodiment 3

A semiconductor device according to an embodiment 3 is generally similar to the semiconductor device 100A according to the embodiment 1, except for a difference in that an amplifier element is flip-chip mounted. Hereunder, description will be given focusing on the difference from the semiconductor device 100A according to the embodiment 1.

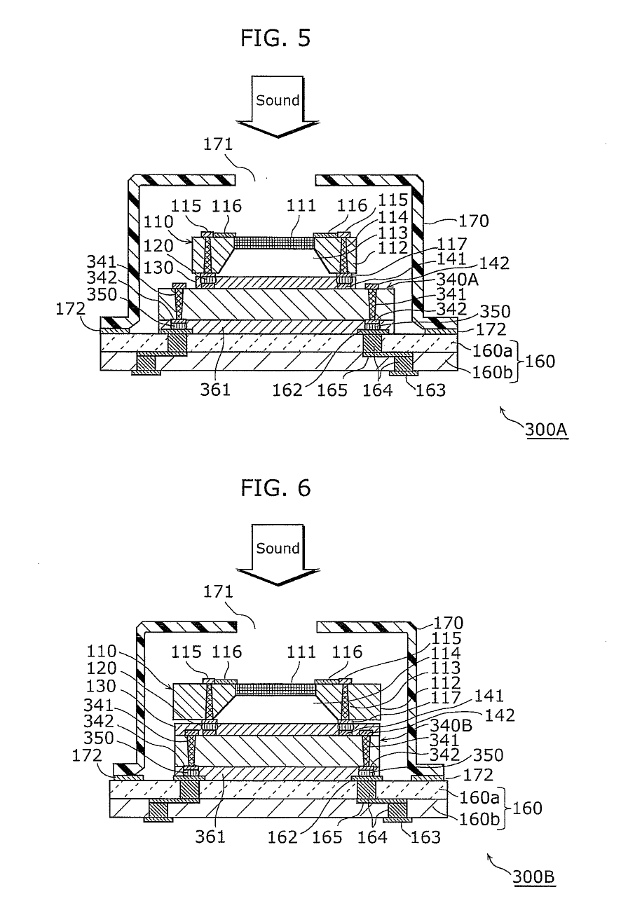

FIG. 5 is a cross-sectional view showing a configuration of the semiconductor device according to this embodiment. As shown therein, the semiconductor device 300A is different from the semiconductor device 100A in that the amplifier element 340A is flip-chip mounted on the substrate 160. The semiconductor device 300A is also different in including bumps 350 corresponding to the second bump as a substitute for the wire 150, for electrically connecting the amplifier element 340A and the substrate 160, because of the configuration in which the amplifier element 340A is flip-chip mounted. In addition, an amplifier element underfill 361 is loaded between the amplifier element 340A and the substrate 160, as a substitute for the element adhesive 161.

Further, the amplifier element 340A includes, unlike the amplifier element 140A, an amplifier element through hole conductor 341 corresponding to the second through conductor penetrating through the amplifier element 340A from the upper face to the lower face thereof, and a lower face electrode 342 located on the lower face of the amplifier element 340A.

The amplifier element through hole conductor 341 serves to electrically connect the electrode 142 on the upper face of the amplifier element 340A and the lower face electrode 342 in a vertical direction. With such a configuration, the electrical signal amplified in the amplifier element 340A is transmitted to the substrate 160 through the electrode 142, the amplifier element through hole conductor 341, the lower face electrode 342, and the bumps 350.

The amplifier element underfill 361 serves to protect the bumps 350, and to ensure and maintain the adherence between the amplifier element 340A and the substrate 160. The amplifier element underfill 361 may be constituted of, for example, a thermosetting resin that cures upon being subjected to heat.

Thus, the semiconductor device 300A according to this embodiment can eliminate, unlike the semiconductor device 100A, the need to secure a space for locating the wire 150 because the amplifier element 340A is flip-chip mounted on the substrate 160, and therefore can be manufactured in a smaller plan-view size.

The manufacturing method of the semiconductor device 300A thus configured will be described hereunder. The semiconductor device 300A according to this embodiment can be manufactured through generally the same process as that of the semiconductor device 100A according to the embodiment 1, except that the amplifier element 340A is bonded onto the substrate 160 by means of the bumps 350, after which the amplifier element underfill 361 is introduced for protecting the bumps. Hereunder, description will be given focusing on the difference from the manufacturing method according to the embodiment 1.

First the substrate 160 is prepared, on the upper surface of which the amplifier element 340A is mounted by connecting the substrate electrode 162 and the lower face electrode 342 by means of the bumps 350.

The amplifier element underfill 361 is then introduced in order to ensure and maintain the adherence of the lower face electrode 342, the bumps 350, and the substrate electrode 162.

Then the converter 110, which includes the vibration film 111 and the cavity 113 covered with the vibration film 111, is mounted on the upper face of the amplifier element 340A by connecting the electrode 141 and the converter electrode 117 by means of the bump 350, with the cavity 113 oriented toward the amplifier element 340A.

Thereafter, the converter underfill 130 is introduced in order to ensure and maintain the adherence of the electrode 141, the bumps 350, and the converter electrode 117, and heat is applied for hardening the converter underfill 130 and the amplifier element underfill 361. It is preferable to employ the same material as the amplifier element underfill 361 and the converter underfill 130, for example a thermosetting resin that cures upon being subjected to heat. Employing thus the material of an equivalent nature as the amplifier element underfill 361 and the converter underfill 130 facilitates the underfill to be cured in the same process, thereby improving mass-production efficiency.

Finally the shield cap 170 having the orifice 171 is fixed onto the upper surface of the substrate 160 with the cap adhesive 172 so as to cover the amplifier element 340A and the converter 110 now connected.

The semiconductor device 300A according to this embodiment can thus be obtained.

Here, different materials may be employed as the amplifier element underfill 361 and the converter underfill 130. In the foregoing process the same material of the same viscosity is employed as both of the amplifier element underfill 361 and the converter underfill 130, and therefore the amplifier element underfill 361 and the converter underfill 130 are introduced in different steps. However, for example, a material having lower viscosity may be employed as the amplifier element underfill 361, because the lower face of the amplifier element 340A has a larger plan-view size. Such an arrangement allows the amplifier element underfill 361 and the converter underfill 130 to be introduced in the same process, thereby improving mass-production efficiency.

Alternatively, the amplifier element underfill 361 and the converter underfill 130 may be provided by application, in the process of bonding the bumps 120 and 350.

The amplifier element underfill 361 and the converter underfill 130 may be substituted with a tape material or the like.

Although the converter underfill 130 is provided for ensuring adherence of the bumps 120 in this embodiment, a space corresponding to the pitch between the bumps 120 is created between the adjacent bumps 120 in the case where sufficient bonding strength can be secured without the converter underfill 130. This allows air in the cavity 113 of the converter 110 to flow out into the space enclosed by the shield cap 170 thereby providing an effect equivalent to an increase in the volume of the rear space, which results in improved microphone sensitivity of the semiconductor device 300A and in upgraded sound quality.

Further, although the amplifier element 340A and the substrate 160 are bonded by means of the bumps 350 before mounting the converter 110 on the amplifier element 340A in this embodiment, the converter 110 may be first mounted on the amplifier element 340A before connecting the amplifier element 340A and the substrate 160 by means of the bumps 350.

Although the semiconductor device 300A and the manufacturing method thereof according to this embodiment have been described thus far, this embodiment may be modified in various manners.

For example, the amplifier element and the converter 110 may have the same plan-view size.

FIG. 6 is a cross-sectional view showing a configuration of a semiconductor device including the converter 110 and the amplifier element having the same plan-view size. A semiconductor device 300B shown in FIG. 6 is different from the semiconductor device 300A shown in FIG. 5 in that an amplifier element 340B and the converter 110 have the same plan-view size. Here, “the same plan-view size” refers to the case where a difference in downwardly projected area is not more than 5%, preferably not more than 2%.

Thus, the amplifier element 340B can be made smaller in plan-view size by manufacturing the converter 110 and the amplifier element 340B in the same plan-view size, and therefore the semiconductor device 300B can be manufactured in a still smaller size and a still lighter weight than the semiconductor device 300A.

To manufacture the semiconductor device 300B, a semiconductor wafer including a plurality of amplifier elements 340A and a wafer including a plurality of converters 110 are bonded by means of the bumps 120. Then the two wafers bonded together, respectively including the plurality of amplifier elements 340A and the plurality of converters 110, are subjected to a dicing process, so that individual bonded pieces of the amplifier element 340A and the converter 110 are obtained. The individual bonded pieces of the amplifier element 340A and the converter 110 are then each bonded to the substrate 160 by means of the bumps 350 and the shield cap 170 is mounted, and thus the semiconductor device 300B can be obtained.

Thus, bonding two wafers respectively including the amplifier elements 340A and the converters 110 and performing the dicing process so as to obtain the individual bonded pieces of the amplifier element 340A and the converter 110 at the same time shortens the processing time, thereby enabling reduction of the manufacturing cost of the semiconductor device 300B.

Alternatively, for example, the shield cap 170 may be excluded from the semiconductor device, and the converter 110, the amplifier element 340A, and the substrate 160 may all be manufactured in the same plan-view size.

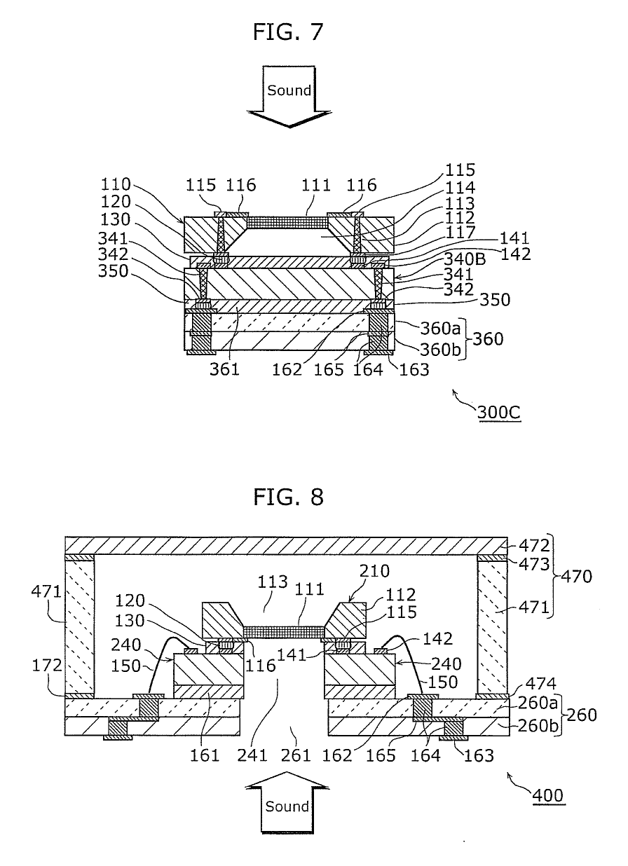

FIG. 7 is a cross-sectional view showing a configuration of a semiconductor device without the shield cap, in which the converter 110, the amplifier element 340B, and the substrate have the same plan-view size. A semiconductor device 300C shown in FIG. 7 is different from the semiconductor device 300B shown in FIG. 6 in that the amplifier element 340B, the converter 110, and a substrate 360 all have the same plan-view size, and that the shield cap 170 is excluded. More specifically, the substrate 360 constituted of an upper substrate 360a and a lower substrate 360b, the amplifier element 340B, and the converter 110 have the same plan-view size. Such a configuration allows the semiconductor device 300C to be manufactured in an even smaller size and lighter weight than the semiconductor device 300B.

The semiconductor device 300C can be manufactured through a process similar to the manufacturing process of the semiconductor device 300B. First a semiconductor wafer including a plurality of amplifier elements 340B and a wafer including a plurality of converters 110 are bonded by means of the bumps 120, after which the two wafers bonded together, respectively including the amplifier elements 340B and the converters 110, are subjected to a dicing process, so that individual bonded pieces of the amplifier element 340B and the converter 110 are obtained. Then the individual bonded pieces of the amplifier element 340B and the converter 110 are each bonded to the substrate 360 by means of the bumps 350, and thus the semiconductor device 300C can be obtained.

Alternatively, the two wafers bonded together, respectively including the plurality of amplifier elements 340B and the plurality of converters 110 may be bonded to a parent substrate including a plurality of substrates 360, and then the amplifier elements 340B, the converters 110, and the substrates 360 may be diced into individual bonded pieces at the same time. Such an arrangement further shortens the processing time thus enabling further reduction of the manufacturing cost.

### Embodiment 4

A semiconductor device according to an embodiment 4 is different from the semiconductor device 100A according to the embodiment 1 in that the shield cap includes a frame surrounding the lateral faces of the converter 210 and the amplifier element 240, and a plate attached to the upper end portion of the frame.

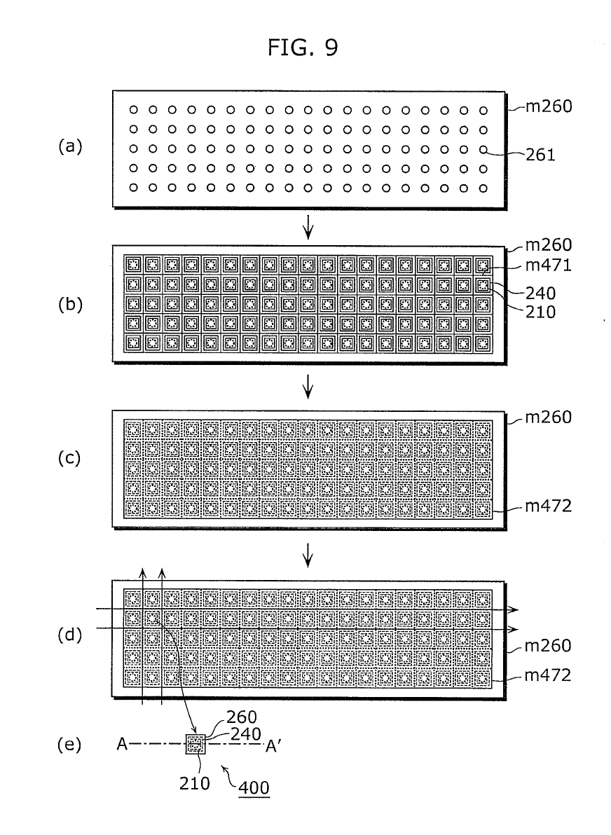

FIG. 8 is a cross-sectional view showing a configuration of the semiconductor device according to the embodiment 4, and FIG. 9 is a series of plan views for explaining a manufacturing method of the semiconductor device according to the embodiment 4.

A semiconductor device 400 shown in FIG. 8 is similar to the semiconductor device 200A shown in FIG. 3, except that a shield cap 470 includes a rib 471 corresponding to the frame, located so as to surround the lateral faces of the converter 210 and the amplifier element 240, and a plate cap 472 which is the plate mounted on the rib 471. The plate cap 472 is fixed to the upper end portion of the rib 471 with an upper adhesive 473. Thus, the shield cap 470 is formed of the rib 471, the plate cap 472 and the upper adhesive 473 serves to cover the converter 210 and the amplifier element 240, as the shield cap 270A of the semiconductor device 200A. The shield cap 470 thus formed is fixed onto the substrate 260 with a lower adhesive 474.

Hereunder, a manufacturing method of the semiconductor device 400 thus configured will be described.

The manufacturing method of the semiconductor device 400 can be defined as a manufacturing method of a semiconductor device including a converter that converts an acoustic pressure into an electrical signal, the converter including a pedestal that includes a first through hole formed from an upper face to a lower face thereof, and a vibration film located on the lower face of the pedestal so as to cover the first through hole and configured to vibrate in accordance with the acoustic pressure to thereby convert the acoustic pressure into an electrical signal; a semiconductor element that includes a second through hole and amplifies the electrical signal converted by the converter; a substrate that includes a third through hole and transmits the electrical signal amplified by the semiconductor element to outside; a frame surrounding a lateral face of the converter and the semiconductor element; and a plate fixed to the frame. The manufacturing method includes assembling a first parent material including a plurality of the substrates, a second parent material including a plurality of the frames, and a third parent material including a plurality of the plates; simultaneously cutting with a dicing blade the first parent material, the second parent material, and the third parent material that have been assembled, to thereby obtain a plurality of the semiconductor devices.

Referring to FIG. 9, the manufacturing method will be described in details hereunder.

First, a parent substrate m260 corresponding to the first parent material is prepared that includes a plurality of substrates 260 each including the substrate electrode 162 on the upper surface and the mounting electrode 163 on the lower surface, and also the substrate through hole 261 corresponding to the third through hole (see (a) in FIG. 9). The parent substrate m260 may include, for example, the plurality of substrates 260 arranged in a matrix. The substrate electrode 162 and the mounting electrode 163 of the substrate 260 are electrically connected to each other. Although the substrate 260 shown in FIG. 8 has a bilayer structure including the upper substrate 260a and the lower substrate 260b, the substrate 260 may be a monolayer substrate in the case where the number of mounting electrodes 163 or rows thereof is not restricted. To increase the number of mounting electrodes 163 or rows thereof, it is preferable to employ a multilayer substrate constituted of two or more layers. In addition, although the substrate 260 is assumed to be a popular resin-based organic substrate in the configuration shown in FIG. 8, the substrate 260 may be constituted of a metal material such as Cu or Fe used for a lead frame, or an inorganic material such as a ceramic. In particular, a major feature of the substrate 260 is that the substrate through hole 261 is provided so as to penetrate therethrough.

Referring to (b) in FIG. 9, the amplifier elements 240 are bonded to the upper surface of the parent substrate m260 with the element adhesive 161 so as to align the amplifier element through hole 241, which is the second through hole, with the corresponding substrate through hole 261, and the electrode 142 of each amplifier element 240 and the corresponding substrate electrode 162 are connected by the wire 150. Here, the element adhesive 161 is applied so as not to interfere with the substrate through hole 261 of the substrate 260. Further, on the upper face of each amplifier element 240 the electrode 141 and the converter electrode 115 are connected by means of the bumps 120, such that the side of the converter 210 with the vibration film 111 is oriented toward the amplifier element 240.

Then the converter underfill 130 is introduced in order to ensure and maintain the adherence of the electrode 141, the bumps 120, and the converter electrode 115, and heat is applied for hardening the converter underfill 130. Here, the converter underfill 130 is loaded such that the vibration film 111 of the converter 210 and the amplifier element through hole 241 can remain spatially continuous, in other words so as not to interfere with the space defined by the amplifier element through hole 241 as far as the vibration film 111. Thus, the substrate through hole 261 and the amplifier element through hole 241 are spatially continuous as far as the vibration film 111. The converter underfill 130 may be constituted of, for example, a thermosetting resin that cures upon being subjected to heat.

The converter underfill 130 may be provided by application in the process of bonding the electrode 141 and the converter electrode 115 by means of the bumps 120. In addition, the converter underfill 130 may be substituted with a tape material or the like. Further, although the electrode 142 of the amplifier element 240 and the substrate electrode 162 are connected by the wire 150 before mounting the converter 210 on the amplifier element 240 in this embodiment, the converter 210 may be first mounted on the amplifier element 240 before connecting the electrode 142 and the substrate electrode 162 by the wire 150.

Then the second parent material, namely a rib parent material m471 including a plurality of frames or ribs 471 is mounted on the parent substrate m260 with the lower adhesive 474, so as to cover each amplifier element 240 and converter 210 now connected.

Proceeding to (c) in FIG. 9, a third parent material including a plurality of plates, i.e., a plate cap parent material m472 including a plurality of plate caps 472 is fixed onto the rib parent material m471 with the upper adhesive 473. A thermosetting resin of an equivalent material is employed as the lower adhesive 474 and the upper adhesive 473, and the lower adhesive 474 and the upper adhesive 473 are subjected to heat of approx. 150 to 250° C. after the plate caps 472 are mounted, and hardened in an N₂ atmosphere for preventing oxidation.

Then a tape is attached to the lower surface of the parent substrate m260.

Referring now to (d) in FIG. 9, the parent substrate m260, the rib parent material m471, and the plate cap parent material m472 are simultaneously cut with a dicing blade or the like as indicated by arrows shown in (d) in FIG. 9, so that a plurality of semiconductor devices 400 retained by the tape is obtained. Here, the dicing blade is set so as not to cut the tape attached to the lower surface of the parent substrate m260. The grain on the dicing blade may be a diamond for example, and may be CBN instead. To bond the grain to the dicing blade, for example a Cu—Sn-based metal bond may be employed. Alternatively, a Ni-based thermosetting resin may be employed for bonding the grain.

Attaching the tape on the lower surface of the parent substrate m260 provides the following advantages. In the cutting process with the dicing blade, normally cutting water is used for cooling and removing cut chips. Accordingly, the vibration film 111 has to be protected from being damaged by the current force of the cutting water or the cut chips. Attaching the tape on the lower surface of the parent substrate m260 prevents intrusion of the cutting water and the cut chips into the substrate through hole 261, thereby preventing the vibration film 111 from being damaged, which results in improved yield of the manufacturing process.

Alternatively, a vacuum adsorption system may be employed in the dicing process of the parent substrate m260 instead of attaching the tape. In this case, however, since the substrate through hole 261 and the vibration film 111 are spatially continuous, the vibration film 111 has to be protected from being damaged by the vacuum suction force.

Then the semiconductor devices 400 are removed from the tape, and thus the individual pieces of the semiconductor device 400 can be obtained as shown in (e) in FIG. 9. Here, the cross-sectional view of the semiconductor device 400 according to the embodiment 4 shown in FIG. 8 corresponds to the cross-section taken along a line A-A′ in (e) in FIG. 9.

Thus, in the semiconductor device 400 according to the embodiment 4 the shield cap 470 includes the rib 471 surrounding the lateral faces of the converter 210 and the amplifier element 240 and the plate cap 472 attached on top of the rib 471, which facilitates the manufacturing process and enables reduction of the manufacturing cost. In addition, cutting the plate cap parent material m472 and the parent substrate m260 at the same time allows further reduction of the manufacturing cost of the semiconductor device 400. Further, employing the tape for retaining the semiconductor device 400 in the dicing process blade can easily prevent the vibration film 111 from being damaged by the current force of the cutting water or the cut chips. Consequently, the yield of the manufacturing process can be improved.

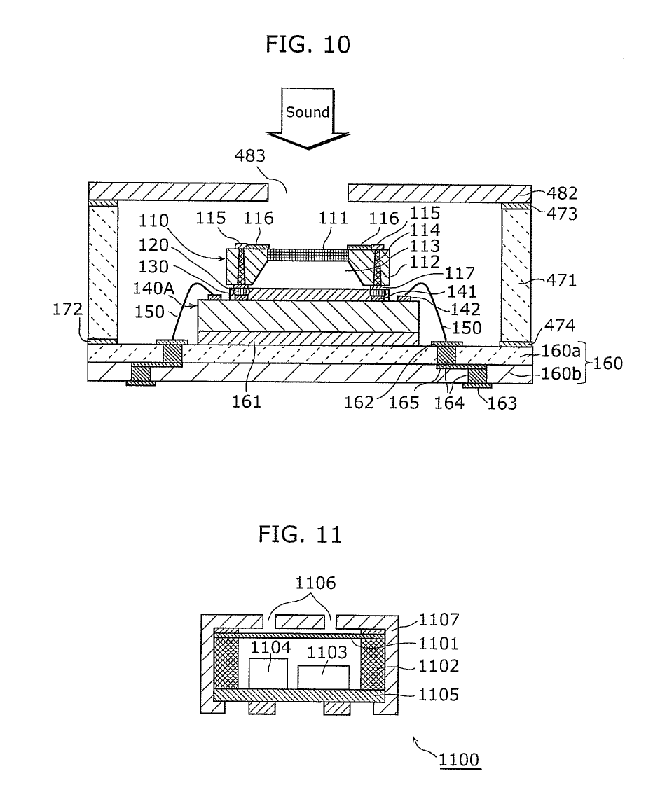

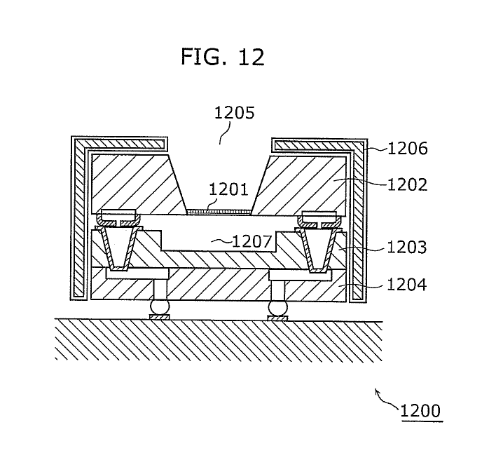

Although the shield cap 470 including the rib 471 and the plate cap 472 is adopted in this embodiment as a substitute for the shield cap 270A of the semiconductor device 200A according to the embodiment 2, the shield cap 470 may be employed in the semiconductor device 100A according to the embodiment 1, as shown in FIG. 10.

FIG. 10 is a cross-sectional view showing a configuration of a semiconductor device including a plate cap 482 having an orifice formed therein, in place of the shield cap. The plate cap 482 is different from the plate cap 472 shown in FIG. 8 in including the orifice 483 which is a through hole, at a position above the vibration film 111.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention provides a semiconductor device having a small size and high microphone sensitivity, and is suitably applicable to digital cameras and mobile phones, which are expected to be made thinner and smaller, yet to provide higher performance.

What is claimed is:

1. A semiconductor device comprising:
a converter that converts an acoustic pressure into an electrical signal;
an electronic part different from said converter;
a substrate on which said converter and said electronic part are mounted; and
a shield member attached to an upper surface of said substrate and formed so as to cover said electronic part and said converter, said converter including:
a pedestal including a first through hole formed therethrough from a first face to a second face opposite the first face; and
a vibration film located so as to cover an opening of the through hole on the side of the first face,
said electronic part being located so as to oppose the first face of said converter thus covering the first through hole, and including a second through hole penetrating therethrough from an upper face to a lower face, at a position overlapping with the first through hole,
said substrate being attached via the upper surface thereof to the lower face of said electronic part, and including a third through hole penetrating therethrough from the upper surface to a lower surface, at a position overlapping with the first through hole and the second through hole,
said shield member including:
a wall portion erected on the upper face of said substrate in a direction in which said electronic part and said converter are stacked, and surrounding a respective lateral face of said electronic part and said converter; and
a top portion located above said converter so as to continuously cover the second face of said converter,
said semiconductor device further comprising:
a first bump located between the upper face of said electronic part and the first face of said pedestal and electrically connecting said vibration film and said electronic part; and
an underfill provided around said first bump,
wherein said first bump and said underfill are located so as to continuously surround the opening of said pedestal on the side of the first face, at a junction of said pedestal and said electronic part; and
said vibration film is set to vibrate in accordance with the acoustic pressure transmitted from outside through the third through hole and the second through hole.

2. The semiconductor device according to claim 1,
wherein the second face of said converter is in contact with the top portion of said shield member.

3. The semiconductor device according to claim 1,
wherein said shield member includes a frame constituting the wall portion and a plate constituting the top portion, and the plate is fixed to an upper face of the frame with an adhesive.

4. The semiconductor device according to claim 1,
wherein the wall portion and the top portion of said shield member are integrally formed.

5. The semiconductor device according to claim 1,
wherein an electrode provided on the upper face of said electronic part and an electrode provided on the upper surface of said substrate are connected to each other by a wire.

6. The semiconductor device according to claim 1, further comprising
a second bump provided between the lower face of said electronic part and the upper surface of said substrate,
wherein said electronic part includes a through conductor penetrating therethrough from the upper face to the lower face; and
said substrate and the through conductor are connected to each other through said second bump.

7. The semiconductor device according to claim 6,
wherein said substrate and said electronic part have substantially the same downwardly projected area.

8. The semiconductor device according to claim 1,
wherein said electronic part is a semiconductor element that amplifies an electrical signal converted by said converter.

9. The semiconductor device according to claim 8,
wherein said substrate transmits to outside an electrical signal amplified by the semiconductor element.

10. The semiconductor device according to claim 1,
wherein said converter converts an acoustic pressure into an electrical signal on the basis of vibration of said vibration film caused by the acoustic pressure.

11. A semiconductor device comprising:
a converter that converts an acoustic pressure into an electrical signal;
an electronic part different from said converter;
a substrate on which said converter and said electronic part are mounted;
said converter including:
a pedestal including a first through hole formed therethrough from a first face to a second face opposite the first face;
a vibration film located so as to cover an opening of the through hole on the side of the first face; and
a first through conductor provided through said pedestal from the first face to the second face,
said electronic part including
a second through conductor provided therethrough from an upper face to a lower face; and
being located so as to oppose the second face of said pedestal thus covering the first through hole,
said substrate being attached via the upper surface thereof to the lower face of said electronic part,
said semiconductor device further comprising:
a first bump located between the upper face of said electronic part and the second face of said pedestal, and connected to the first through conductor thus electrically connecting said vibration film and said electronic part;
an underfill provided between the upper face of said electronic part and the second face of said pedestal, and around said first bump; and
a second bump located between the lower face of said electronic part and the upper surface of said substrate, and electrically connecting the second through conductor and said substrate,
wherein said substrate and said electronic part have substantially the same downwardly projected area.

12. The semiconductor device according to claim 11,
wherein said electronic part is a semiconductor element that amplifies an electrical signal converted by said converter.

13. The semiconductor device according to claim 12,
wherein said substrate transmits to outside an electrical signal amplified by the semiconductor element.

14. The semiconductor device according to claim 11,
wherein said converter converts an acoustic pressure into an electrical signal on the basis of vibration of said vibration film caused by the acoustic pressure.
